(19) United States
(12) Patent Application Publication
(10) Pub. No.: US 2011/0198619 A1
(43) Pub. Date: Aug. 18, 2011

(54) LIGHT EMITTING DIODE ASSEMBLY HAVING IMPROVED LIGHTING EFFICIENCY

(75) Inventors: Chung-I CHIANG, Taoyuan (TW); Hung-Yi Lin, Taoyuan (TW); Hsien-Lung Ho, Taoyuan (TW)

(73) Assignee: WALSIN LIHWA CORPORATION, Taoyuan (TW)

(21) Appl. No.: 12/707,993

(22) Filed: Feb. 18, 2010

(51) Int. Cl. H01L 33/00

(52) U.S. Cl. 257/88; 257/E33.068

(57) ABSTRACT

A light emitting diode assembly is disclosed in the present invention. The light emitting diode assembly has a substrate and several light emitting diode units. It can also include several light emitting diode units fabricated on cavities formed in the substrate. Any light emitting diode unit is composed of a light emitting diode chip covered with a phosphor layer for providing light beams, and a reflecting unit installed or formed on the substrate, coated with a reflective film, surrounding the light emitting diode chip for reflecting the light beams emitted from the light emitting diode chip, and directing the light beams upward. The light emitting diode unit further includes a light condenser provided above the light emitting diode chip for guiding the light beams upward. The assembly can collect all light beams emitted laterally. Hence, lighting efficiency for the light emitting diode assembly can be improved.

### FIELD OF THE INVENTION

The present invention relates generally to a light emitting diode assembly. More specifically, the present invention relates to a light emitting diode assembly having a condenser for guiding light beams.

### BACKGROUND OF THE INVENTION

When a light emitting diode is used, light extraction efficiency of the light emitting diode is dominated by its internal quantum efficiency and light extraction efficiency. Internal quantum efficiency relates to the efficiency of light generated from an active layer. Light extraction efficiency is the ability that the light from the active layer emits to medium surrounded. With development of epitaxy technology, internal quantum efficiency can be up to 80%. However, light extraction efficiency is still low. For example, refraction index of GaN-based materials is about 2.5. The air around them has refraction index of 1. Due to total reflection, the light extraction efficiency in the interface is only 10˜12%.

In order to have better light extraction efficiency, many solutions have been provided. Therefore, high brightness light emitting diodes are available nowadays. When we look at applications of these light emitting diodes, there are still some shortcomings that need to be improved. For example, when a light emitting diode is used as a light source, a special lampshade is required. This is because light emitting diode is a scattering light source. Like conventional lamps, it needs a lampshade to collect all light beams including the light beams emitting laterally. The lampshade can not be too small for practice use and heat sink. However, if the light emitting diode is used as a backlighting source of a liquid crystal display or an indicator of traffic signals, it is better for the lighting set (the light emitting diode and lampshade) to be as small as possible.

In order to solve the problems, some prior arts have shown different solutions. Please refer to FIG. 1. U.S. Pat. No. 6,987,613 provides a light emitting device including a Fresnel lens or a holographic diffuser formed on a surface of a semiconductor light emitter for improved light extraction. '613 uses the Fresnel lens or holographic diffuser to guide some scattering light out of the light emitting diode below. It has the function of collimation of light beams and small size. However, there are still some light beams emitted laterally which can not be efficiently used.

Please refer to FIG. 2. U.S. Pat. No. 7,145,181 provides an improvement over '613 patent. It shows a light-emitting diode having a substrate, on which a sequence of semiconductor layers with an active zone are been applied. Above the sequence of semiconductor layers there is a stepped window layer which is structured in the manner of a Fresnel lens and has with regard to the coupling out of radiation the function of a hemispherical lens. Obviously, the invention may be more easily to be achieved. It still remains the same defect to utilize lateral light beams.

Last, please refer to FIG. 3. US Publication Number 20070034890 provides a light emitting device which includes a number of light emitting diode dies mounted on a shared submount and covered with a single lens element that includes a corresponding number of lens elements. The LEDs are separated from each other by a distance that is sufficient for lens element to include separate lens elements for each LED. The separation of the LEDs and lens elements may be configured to produce a desired amount of light on a target at a predefined distance. The lens elements are approximately flat type lens elements, such as Fresnel, TIR, diffractive lens, photonic crystal type lenses, prism, or reflective lens. The structure has better lighting efficiency than the mentioned prior arts. However, utilization of lateral light beams could be further improved.

Therefore, a light emitting diode assembly providing collimated light beams, having small size and well utilizing lateral light beams is still desired.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims.

In accordance with an aspect of the present invention, a light emitting diode assembly having improved lighting efficiency includes a flat substrate; and a plurality of light emitting diode units each having: a light emitting diode chip covered with a phosphor layer for providing light beams; a reflecting unit installed on the flat substrate, coated with a reflective film, surrounding the light emitting diode chip for reflecting the light beams emitted from the light emitting diode chip, and directing the light beams upward; and a light condenser provided above the light emitting diode chip by connecting with edges of the reflecting unit, having a plurality of concentric rings, for guiding the light beams upward.

Preferably, any two adjacent reflecting units have a spacing smaller than 10 μm.

Preferably, the substrate has through silicon vias (TSVs) for electric connection.

Preferably, the substrate is a silicon substrate, a ceramic substrate or a printed circuit board.

Preferably, the reflective film is made of a metal.

Preferably, widths of the concentric rings are equal.

Preferably, the concentric ring having a larger radius has a larger width.

Preferably, the concentric ring having a larger radius has a smaller width.

Preferably, the light condenser is a Fresnel lens.

Preferably, the light condenser is made of epoxy resin, silicone, polyetherimide, fluorocarbon polymer, polymethyl methacrylate (PMMA), polycarbonate (PC), cyclo olefin copolymer (COC), glass or a mixture thereof.

Preferably, the reflecting unit is concave.

Preferably, the reflecting unit is formed by photolithographic process.

In accordance with another aspect of the present invention, a light emitting diode assembly having improved lighting efficiency includes a substrate having a plurality of concave cavities; and a plurality of light emitting diode units each having: a light emitting diode chip located in one of the cavities and covered with a phosphor layer for providing light beams; and a light condenser provided above the light emitting diode chip by connecting with rim of the cavity, having a plurality of concentric rings, for guiding the light beams upward; wherein the cavities are coated with a reflective film for reflecting the light beams emitted from the light emitting diode chips, and directing the light beams upward.

Preferably, any two adjacent cavities have a spacing smaller than 10 μm.

Preferably, the substrate has through silicon vias (TSVs) for electric connection.

Preferably, the substrate is a silicon substrate, a ceramic substrate or a printed circuit board.

Preferably, the reflective film is made of a metal.

Preferably, widths of the concentric rings are equal.

Preferably, the concentric ring having a larger radius has a larger width.

Preferably, the concentric ring having a larger radius has a smaller width.

Preferably, the light condenser is a Fresnel lens.

Preferably, the light condenser is made of epoxy resin, silicone, polyetherimide, fluorocarbon polymer, polymethyl methacrylate (PMMA), polycarbonate (PC), cyclo olefin copolymer (COC), glass or a mixture thereof.

Preferably, the cavities are made by sintering or microelectromechanical technology.

### BRIEF DESCRIPTION OF THE DRAWINGS

FIG. 1 illustrates a prior art of a light emitting diode assembly.

FIG. 2 illustrates another prior art of a light emitting diode assembly.

FIG. 3 illustrates still another prior art of a light emitting diode assembly.

FIG. 4 illustrates a first embodiment of the present invention.

FIGS. 5A-5C are cross-sectional views taken along line AA′ in FIG. 4 showing various alternatives.

FIG. 6 illustrates formation of a condenser in the first embodiment.

FIG. 7 shows other forms of the condenser in the first embodiment.

FIG. 8 illustrates a second embodiment of the present invention.

FIGS. 9A-9C are cross-sectional views taken along line BB′ in FIG. 8 showing various alternatives.

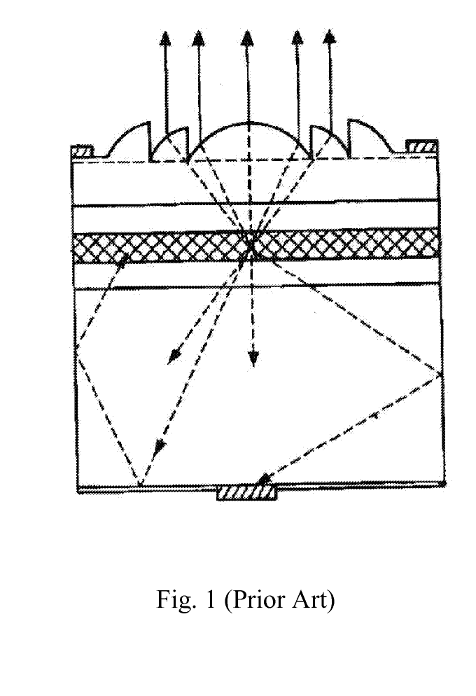

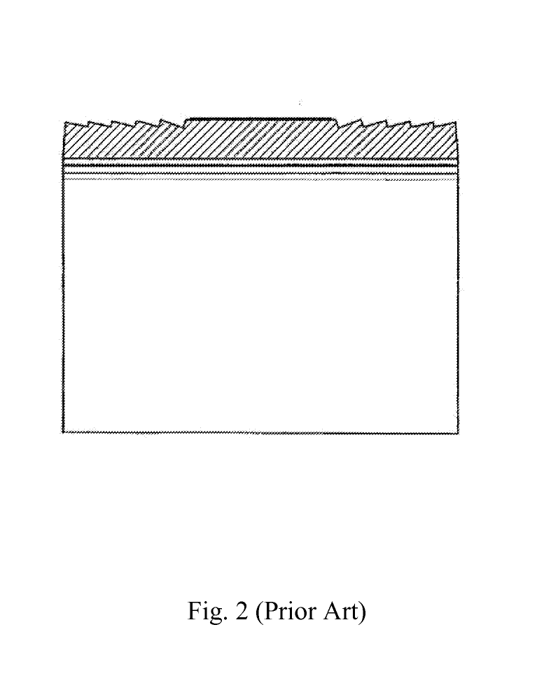

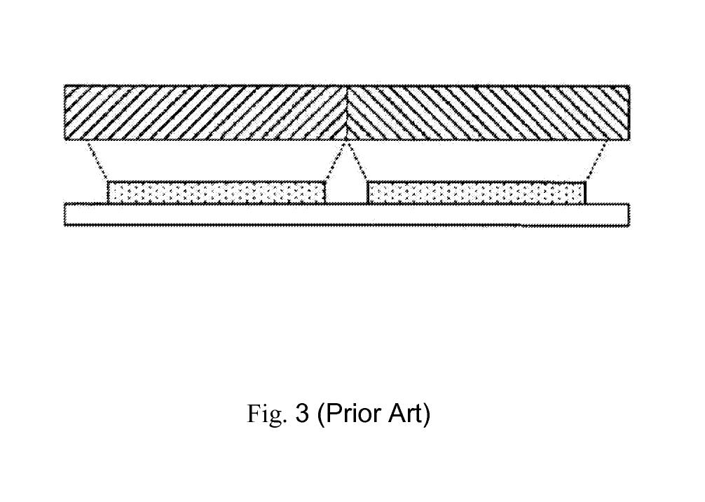

### DETAILED DESCRIPTION OF THE PREFERRED EMBODIMENTS

For better understanding of the present invention, two embodiments are described below.

### First Embodiment

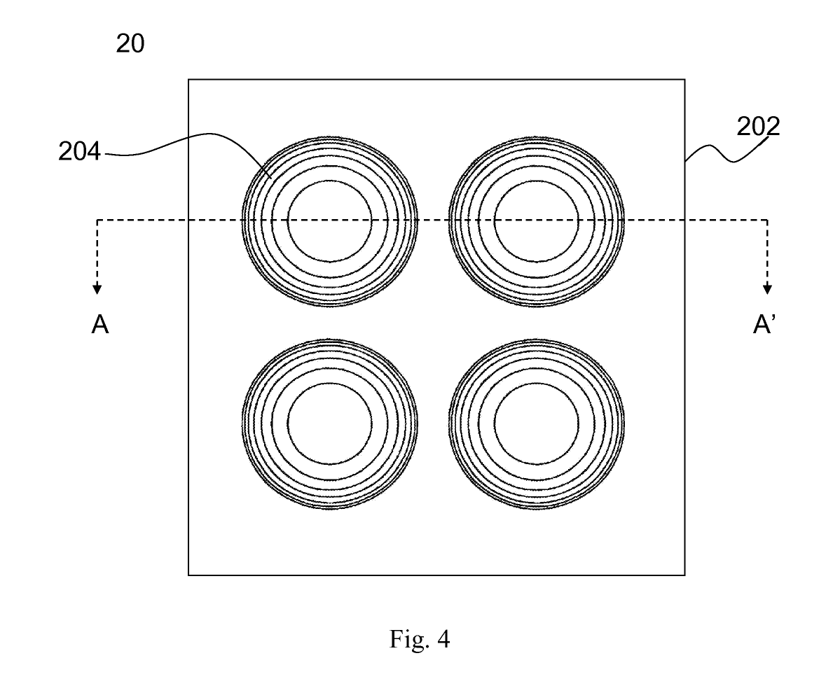

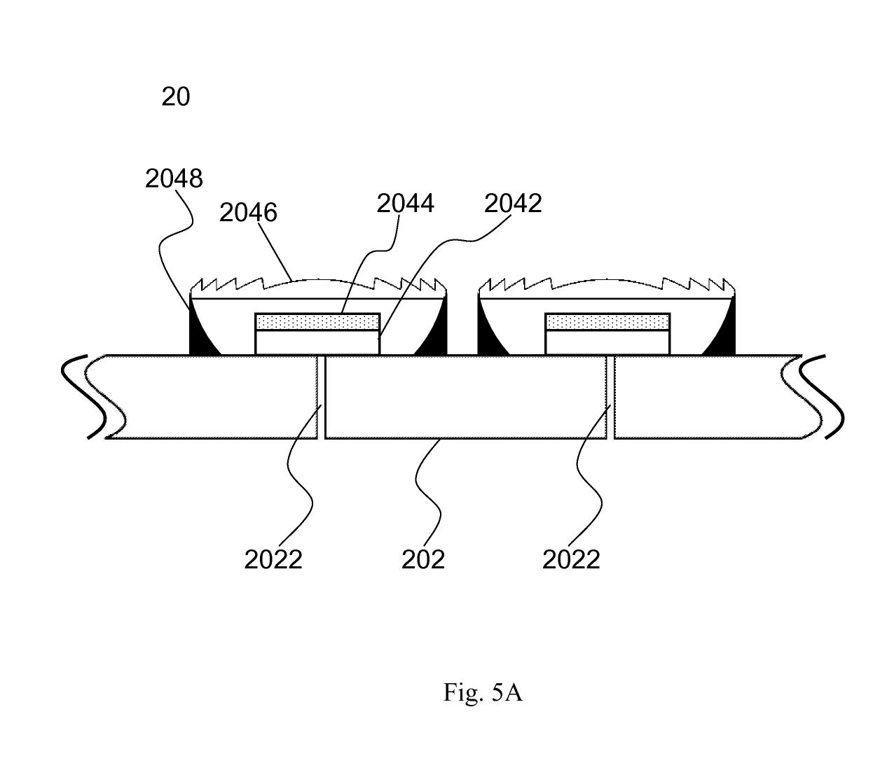

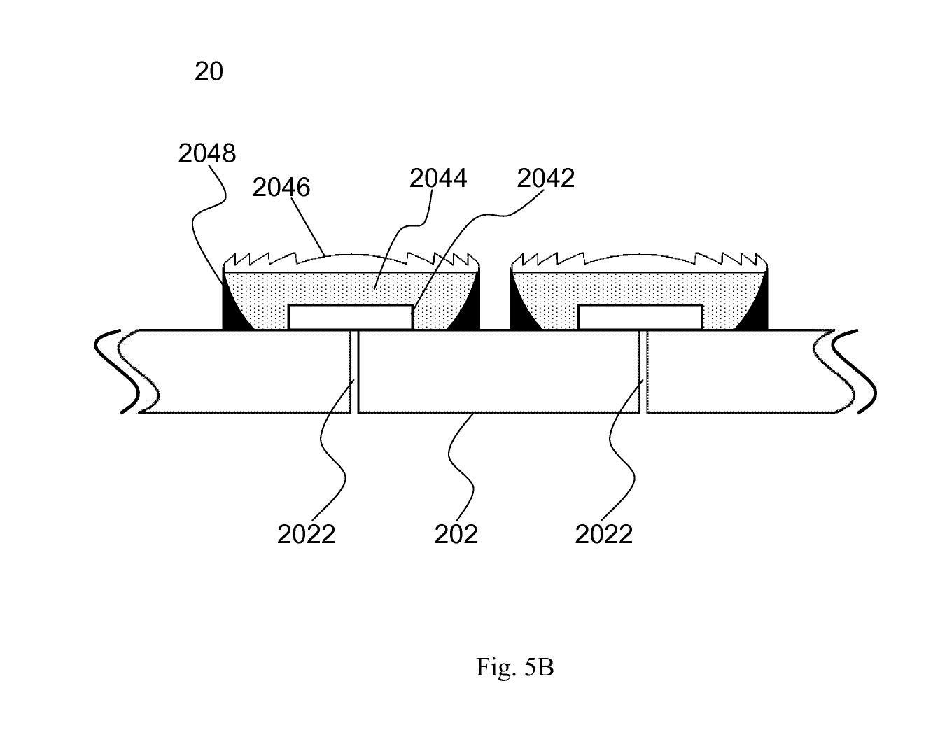

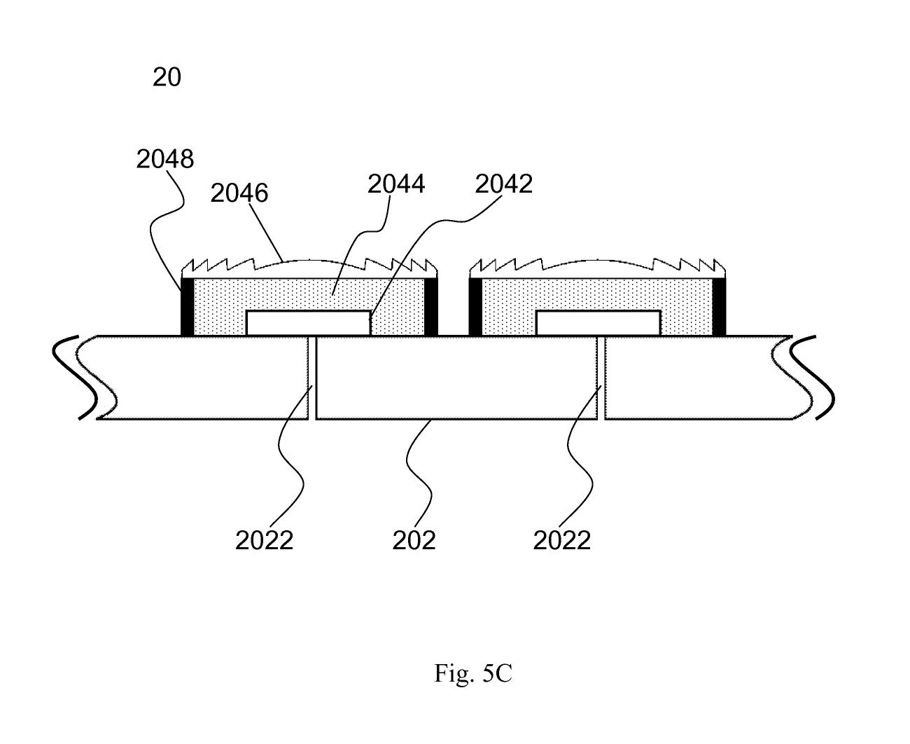

Please refer to FIG. 4 to FIG. 7. A first embodiment is illustrated. A light emitting diode assembly 20 has a flat silicon substrate 202 and four light emitting diode units 204. Structure of the light emitting diode units 204 can be shown by cutting the light emitting diode assembly 20 along line AA′ in the FIG. 4, as shown in FIGS. 5A-5C. Each light emitting diode unit 204 is composed of a light emitting diode chip 2042, a light condenser 2046 and a reflecting unit 2048.

The light emitting diode chip 2042 is covered with a phosphor layer 2044 for providing light beams, as shown in FIG. 5A or FIG. 5B. The light condenser 2046 is provided above the light emitting diode chip 2042 by connecting with edges of the reflecting unit 2048. The light condenser 2046 has many concentric rings to guide the light beams upward so that the light beams can be guided out of the emitting diode assembly 20. The reflecting unit 2048 is installed on the silicon substrate 202 and coated with a reflective film. It is concave and formed by photolithographic process. The reflective film is made of a metal. In the present embodiment, silver is used. The reflecting unit 2048 surrounds the light emitting diode chip 2042 for reflecting the light beams emitted from the light emitting diode chip 2042. It can also direct the light beams upward to the light condenser 2046. The reflecting unit 2048 can be shaped as a bowl having a concave wall, as shown in FIGS. 5A-5B, or the concave wall can be replaced with an upper-right wall, as shown in FIG. 5C.

It should be noticed that any two adjacent reflecting units 2048 have a spacing smaller than 10 μm. The silicon substrate 202 has through silicon vias 2022 (TSVs) for electric connection. That means wires (not shown) can pass through the silicon vias 2022 from the top surface of the silicon substrate 202 to the bottom of the silicon substrate 202 to connect the light emitting diode units 204 with other circuits (not shown).

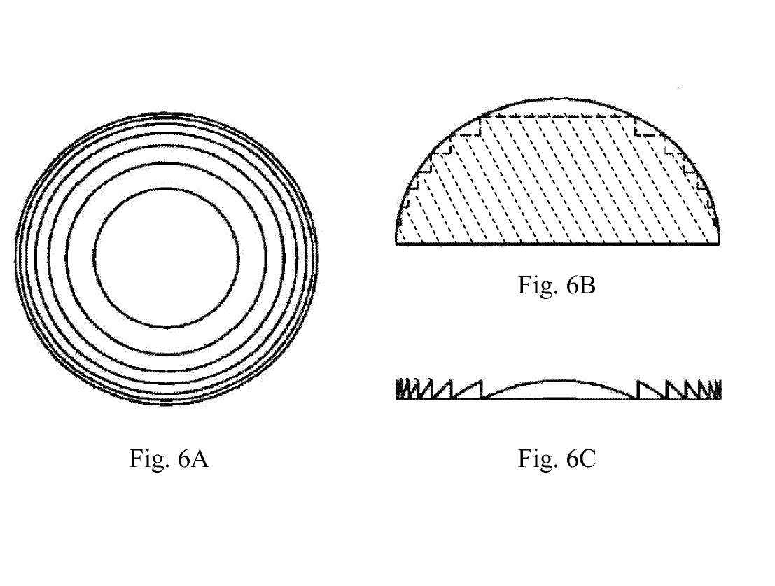

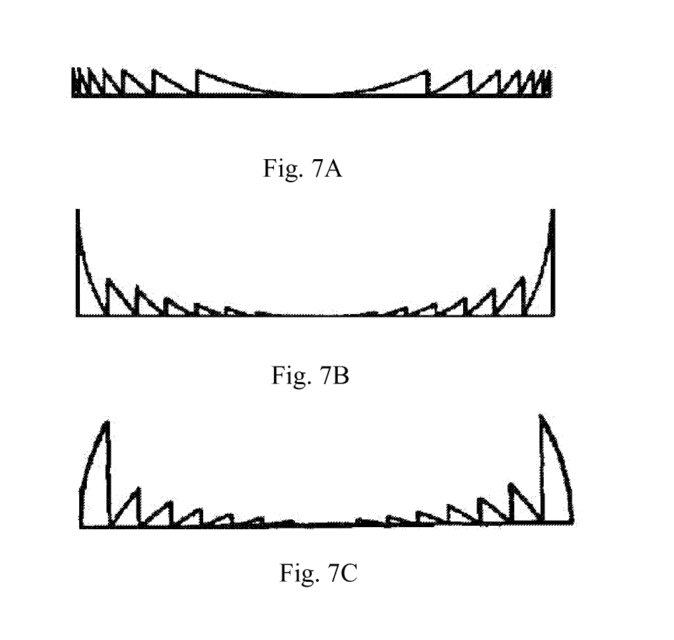

As to the structure of the concentric rings, it is further described with reference to FIGS. 6A to 6C and FIGS. 7A to 7C. FIG. 6B depicts a lens which has unnecessary optical portion (marked with dashed lines) that allows light beams moving in a straight way without changing direction. After removing the unnecessary optical portion and re-arranging the rest part on a plane, the concentric rings are formed in a cross-sectional view in FIG. 6C. As shown, each concentric ring has a triangular-like cross-section. Hence, the cross-sectional view of the light condenser 2046 looks like sawteeth. In the present embodiment, the concentric ring having a larger radius has a smaller width. The concentric ring with a larger radius can have a larger width, too. However, the height of each triangular-like sawteeth can not keep the same.

Due to different cutting methods, the light condenser 2046 has different shapes in the cross-section. Please refer to FIG. 7A, FIG. 7B and FIG. 7C. FIG. 7A shows a second type of light condenser 2046. The light condenser 2046 in FIG. 7A has different triangular-like sawteeth from those shown in FIG. 6C. FIG. 7B shows a third type of light condenser 2046 which has an equal width of the concentric rings. However, height of rings increases from the center to the edge. Similarly, FIG. 7C shows a fourth type of light condenser 2046 which has equal ring width. The only difference from FIG. 7B is the direction of triangular-like sawteeth. In this embodiment, the light condenser 2046 is a Fresnel lens.

Furthermore, the light condenser 2046 is made of epoxy resin. In practice, it can also be made of silicone, polyetherimide, fluorocarbon polymer, polymethyl methacrylate (PMMA), polycarbonate (PC), cyclo olefin copolymer (COC), glass or a mixture of the materials mentioned above. Meanwhile, the silicon substrate 202 can be formed by other materials, such as ceramic. A printed circuit board can also be an ideal carrier to replace the silicon substrate 202.

### Second Embodiment

According to the spirit of the present invention, the substrate is allowed to use coated cavities rather than protruded reflecting units to collect and guide light beams. A second embodiment illustrates how it is achieved.

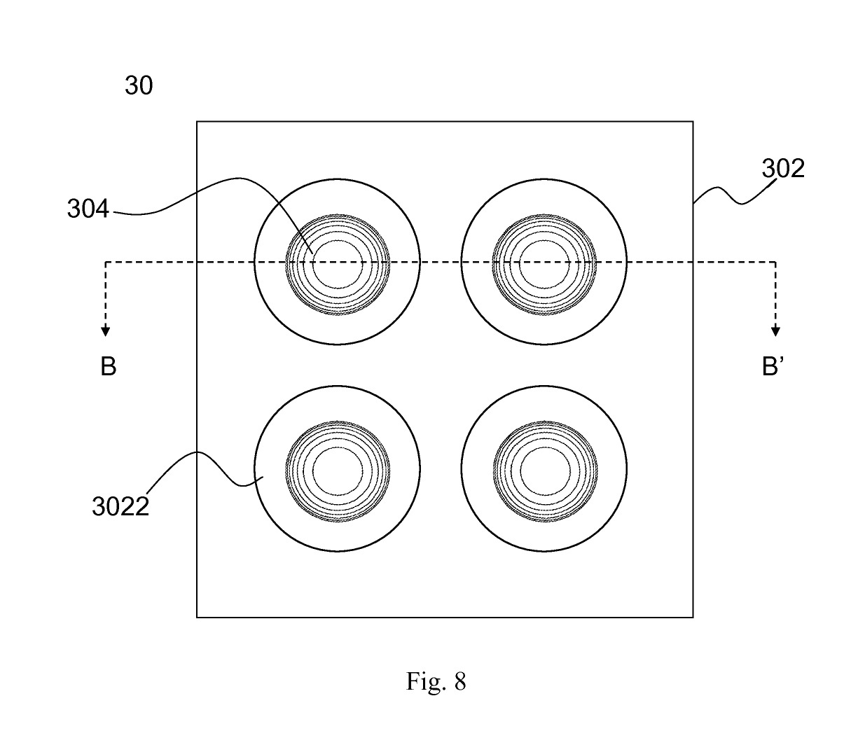

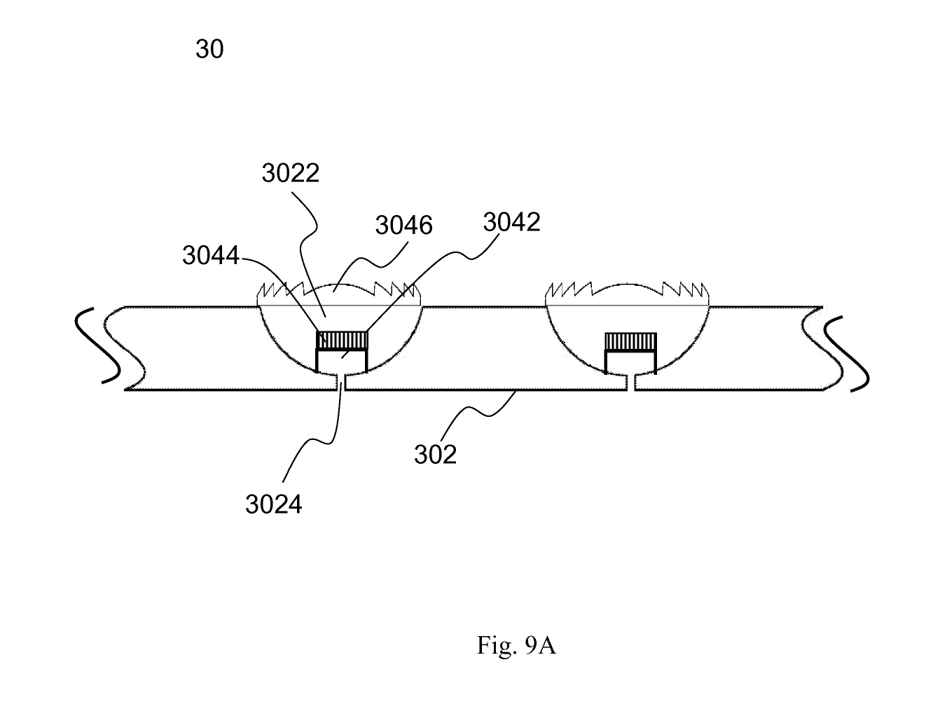

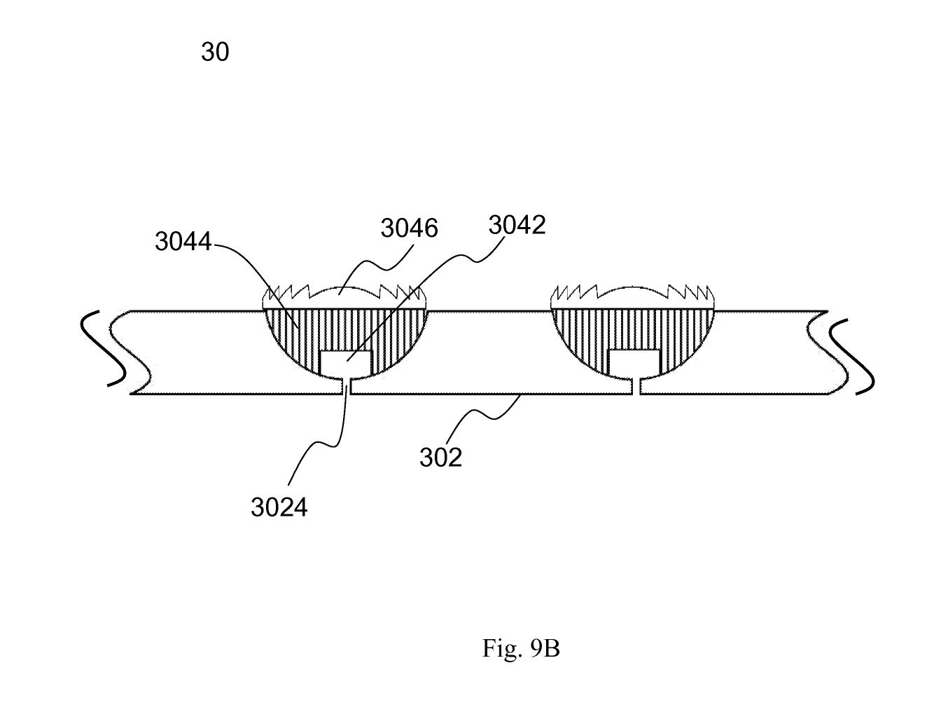

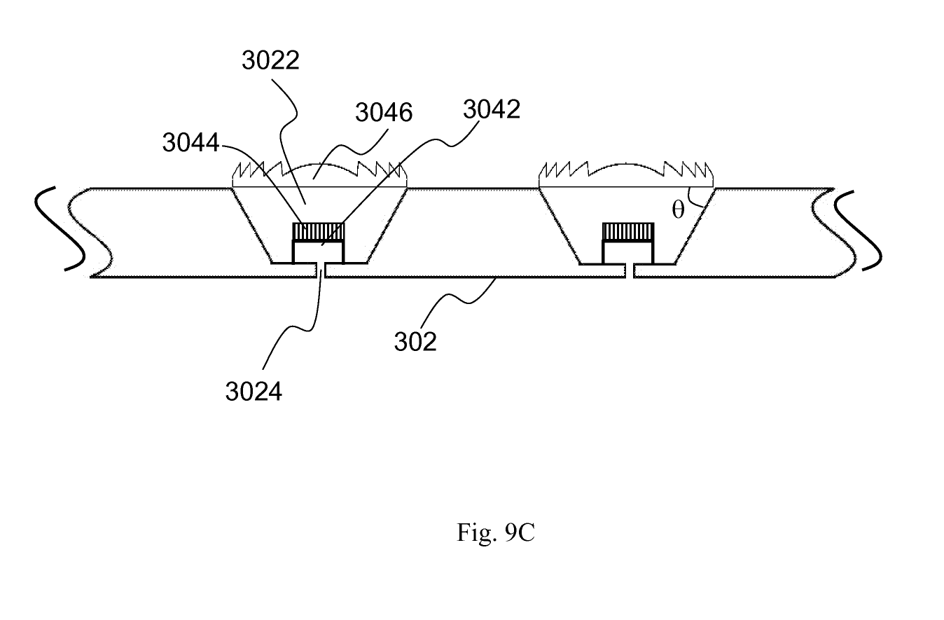

Please refer to FIG. 8 and FIG. 9. A light emitting diode assembly 30 comprises a ceramic substrate 302 and four light emitting diode units 304. Structure of the light emitting diode units 304 can be shown by cutting the light emitting diode assembly 30 along line BB′ in FIG. 8. Four concave cavities 3022 are formed on the top surface of the ceramic substrate 302 and made by sintering.

Each of the light emitting diode units 304 has a light emitting diode chip 3042 located in one of the cavities 3022 and covered with a phosphor layer 3044 for providing light beams and a light condenser 3046, as shown in FIGS. 9A-9C. The light condenser 3046 is provided above the light emitting diode chip 3042 by connecting with rim of the cavity 3022. The light condenser 3046 has many concentric rings to guide the light beams upward so that the light beams can irradiate out of the light emitting diode assembly 30. The cavities 3022 are coated with a reflective film which reflects the light beams emitted from the light emitting diode chips 3042 and directs the light beams upward to the light condenser 3046. In this embodiment, the reflective film is made of silver. Other metal which can reflect the light beams are also applicable.

It is noticed that any two adjacent cavities 3022 have a spacing smaller than 10 μm. The ceramic substrate 302 has through silicon vias 3024 (TSVs) for electric connection. That means wires (not shown) can pass through the silicon vias 3024 from the top surface of the ceramic substrate 302 to the bottom of the ceramic substrate 302 to connect the light emitting diode units 304 with other circuits (not shown).

The cavities 3022 each can be shaped as a bowl by isotropic etching or sintering, as shown in FIGS. 9A-9B. Furthermore, the cavities 3022 can be formed by potassium hydroxide (KOH) wet etching while the substrate is made of silicon, thereby producing a characteristic anisotropic V-etch with sidewalls that form an angle θ of 54.7° with the top surface of the substrate 302.

Like the first embodiment, the light condenser 3046 has different shapes in cross-section. The concentric rings of the light condenser 3046 form triangular-like sawteeth in cross-section. Widths of the concentric rings also have different types. The widths can be equal. Alternatively, the concentric ring having a larger radius has a larger width, or the concentric ring having a larger radius has a smaller width. In the present embodiment, the light condenser 3046 is a Fresnel lens.

Furthermore, the light condenser 3046 is made of epoxy resin. In practice, it can also be made of silicone, polyetherimide, fluorocarbon polymer, polymethyl methacrylate (PMMA), polycarbonate (PC), cyclo olefin copolymer (COC), glass or a mixture of the materials mentioned above. Meanwhile, the ceramic substrate 302 can be formed by other materials, such as silicon. A printed circuit board can also be an ideal carrier to replace the ceramic substrate 302.

While the invention has been described in terms of what is presently considered to be the most practical and preferred embodiments, it is understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A light emitting diode assembly having improved lighting efficiency, comprising:
a flat substrate; and
a plurality of light emitting diode units each having:
a light emitting diode chip covered with a phosphor layer for providing light beams;
a reflecting unit installed on the flat substrate, coated with a reflective film, surrounding the light emitting diode chip for reflecting the light beams emitted from the light emitting diode chip, and directing the light beams upward; and
a light condenser provided above the light emitting diode chip by connecting with edges of the reflecting unit, having a plurality of concentric rings, for guiding the light beams upward.

2. The light emitting diode assembly according to claim 1, wherein any two adjacent reflecting units have a spacing smaller than 10 nm.

3. The light emitting diode assembly according to claim 1, wherein the substrate has through silicon vias (TSVs) for electric connection.

4. The light emitting diode assembly according to claim 1, wherein the substrate is a silicon substrate, a ceramic substrate or a printed circuit board.

5. The light emitting diode assembly according to claim 1, wherein the reflective film is made of a metal.

6. The light emitting diode assembly according to claim 1, wherein widths of the concentric rings are equal.

7. The light emitting diode assembly according to claim 1, wherein the concentric ring having a larger radius has a larger width.

8. The light emitting diode assembly according to claim 1, wherein the concentric ring having a larger radius has a smaller width.

9. The light emitting diode assembly according to claim 1, wherein the light condenser is a Fresnel lens.

10. The light emitting diode assembly according to claim 1, wherein the light condenser is made of epoxy resin, silicone, polyetherimide, fluorocarbon polymer, polymethyl methacrylate (PMMA), polycarbonate (PC), cyclo olefin copolymer (COC), glass or a mixture thereof.

11. The light emitting diode assembly according to claim 1, wherein the reflecting unit is concave.

12. The light emitting diode assembly according to claim 1, wherein the reflecting unit is formed by photolithographic process.

13. A light emitting diode assembly having improved lighting efficiency, comprising:
a substrate having a plurality of concave cavities; and
a plurality of light emitting diode units each having:
a light emitting diode chip located in one of the cavities and covered with a phosphor layer for providing light beams; and
a light condenser provided above the light emitting diode chip by connecting with rim of the cavity, having a plurality of concentric rings, for guiding the light beams upward;
wherein the cavities are coated with a reflective film for reflecting the light beams emitted from the light emitting diode chips, and directing the light beams upward.

14. The light emitting diode assembly according to claim 13, wherein any two adjacent cavities have a spacing smaller than 10 μm.

15. The light emitting diode assembly according to claim 13, wherein the substrate has through silicon vias (TSVs) for electric connection.

16. The light emitting diode assembly according to claim 13, wherein the substrate is a silicon substrate, a ceramic substrate or a printed circuit board.

17. The light emitting diode assembly according to claim 13, wherein the reflective film is made of a metal.

18. The light emitting diode assembly according to claim 13, wherein widths of the concentric rings are equal.

19. The light emitting diode assembly according to claim 13, wherein the concentric ring having a larger radius has a larger width.

20. The light emitting diode assembly according to claim 13, wherein the concentric ring having a larger radius has a smaller width.

21. The light emitting diode assembly according to claim 13, wherein the light condenser is a Fresnel lens.

22. The light emitting diode assembly according to claim 13, wherein the light condenser is made of epoxy resin, silicone, polyetherimide, fluorocarbon polymer, polymethyl methacrylate (PMMA), polycarbonate (PC), cyclo olefin copolymer (COC), glass or a mixture thereof.

23. The light emitting diode assembly according to claim 13, wherein the cavities are made by sintering or microelectromechanical technology.
